(19) United States
(12) Patent Application Publication
(10) Pub. No.: US 2011/0140151 A1
(43) Pub. Date: Jun. 16, 2011

(54) Organic-light emitting device, light equipment including the same, and organic light-emitting display apparatus including the same

(76) Inventors: Sung-Hun Lee, Yongin-City (KR); Chang-Woong Chu, Yongin-city (KR); Gwan-Hyoung Lee, Yongin-city (KR); SeungHyup Yoo, Daejeon-city (KR); Tae-Wook Koh, Daejeon-city (KR)

(21) Appl. No.: 12/926,842

(22) Filed: Dec. 13, 2010

(30) Foreign Application Priority Data
Dec. 14, 2009 (KR) 10-2009-0123991

(51) Int. Cl. H01L 51/50

(52) U.S. Cl. 257/98; 257/E51.018

(57) ABSTRACT

An organic light-emitting device includes a substrate, a first electrode layer on the substrate, a patterned refractive layer on the first electrode layer, a taper angle between a patterned end of the refractive layer and a surface of the first electrode being about 20 to about 60 degrees, the refractive layer including a material having a different refractive index than at least one of the first electrode layer and an organic light-emitting layer, the organic light-emitting layer that covers the refractive layer and is on the first electrode, the organic light-emitting layer contacting the patterned end of the refractive layer, and a second electrode layer on the organic light-emitting layer.

### BACKGROUND

1. Field

Embodiments relate to an organic light-emitting device, light equipment including the same, and an organic light-emitting display (OLED) apparatus including the same.

2. Description of the Related Art

An organic-light emitting device includes an organic light-emitting layer formed between electrodes opposite to each other. Electrons injected from one of the electrodes are combined with holes injected from the other one of the electrodes in the organic light-emitting layer. Molecules that emit light from the organic light-emitting layer are excited and return to a ground state through the combination so as to emit power as light.

The light emitted from the organic light-emitting layer of the organic-light emitting device does not have a predetermined directivity, i.e., the light is emitted in random directions having a statistically homogenous angular distribution. A ratio of the number of photons that are not consumed and actually reach an observer to the total number of photons generated in the organic light-emitting layer of the organic-light emitting device, i.e., out-coupling efficiency “ηₒᵤₜ,” is about 1/(2_{ηorg}²), where a reflective index of the organic light-emitting layer is “η_{org}.” If a general refractive index “η_{org}” of 1.75 is substituted for the reflective index “η_{org}” of the organic light-emitting layer, the out-coupling efficiency “ηₒᵤₜ” is about 16%.

The out-coupling efficiency “ηₒᵤₜ” of the organic-light emitting device limits overall an external quantum efficiency and a power factor. The external quantum efficiency and the power factor determine a total amount of consumed power of the organic-light emitting device and thus greatly affect a lifespan of the organic-light emitting device. Accordingly, many efforts to increase an external quantum efficiency and a power factor have been made.

### SUMMARY

It is a feature of an embodiment to provide an organic light-emitting device for improving out-coupling efficiency, and light equipment including the organic light-emitting device, and an organic light-emitting display (OLED) apparatus including the organic-light emitting device.

At least one of the above and other features and advantages may be realized by providing an organic light-emitting device, including a substrate, a first electrode layer on the substrate, a patterned refractive layer on the first electrode layer, a taper angle between a patterned end of the refractive layer and a surface of the first electrode being about 20 to about 60 degrees, the refractive layer including a material having a different refractive index from that of one of the first electrode layer and an organic light-emitting layer, the organic light-emitting layer that covers the refractive layer and is on the first electrode, the organic light-emitting layer contacting the patterned end of the refractive layer, and a second electrode layer on the organic light-emitting layer.

At least one of the first and second electrode layers may be a transparent electrode.

The refractive layer may have a lower refractive index than that of one of the organic light-emitting layer and the first electrode layer

The refractive index of the refractive layer may be about 1 to about 1.55.

The refractive layer may be transparent to visible light, and may include at least one of a porous material, a fluorinated compound, an oxide, a nitride, a silicon compound, and a polymer organic material.

The taper angle may be about 30 to about 60 degrees.

The refractive layer may be regularly patterned, and may be parallel with the first and second electrode layers.

A periodic interval of the pattern of the refractive layer may be larger than a wavelength of light emitted from the organic light-emitting device.

The taper angle may be about 30 to about 60 degrees.

The refractive layer may have a higher refractive index than that of one of the organic light-emitting layer and the first electrode layer.

The refractive index of the refractive layer may be about 1.9 to about 2.8.

The refractive layer may be transparent to visible light, and may include at least one of a carbide, an oxide, a nitride, a sulfide, and a selenium compound.

The refractive layer may be regularly patterned, and may be parallel with the first and second electrode layers.

A periodic interval of the regularly patterned refractive layer may be larger than a wavelength of light emitted from the organic light-emitting device.

The taper angle may be about 30 to about 60 degrees.

The organic light-emitting device may further include a microlens array (MLA) on an outer surface of the substrate, the MLA having a refractive index of about 1.45 to about 1.8.

The MLA may have a periodic interval.

A size and a periodic interval of the MLA may be larger than a wavelength of light emitted from the organic light-emitting device.

The MLA may be transparent to visible light, and may include at least one of an oxide, a nitride, a silicon compound, and a polymer organic material.

At least one of the above and other features and advantages may also be realized by providing a light equipment including an organic-light emitting device according to an embodiment.

At least one of the above and other features and advantages may also be realized by providing an organic light-emitting display apparatus including an organic light-emitting device according to an embodiment.

### BRIEF DESCRIPTION OF THE DRAWINGS

The above and other features and advantages will become more apparent to those of skill in the art by describing in detail example embodiments with reference to the attached drawings, in which:

FIG. 1 illustrates a schematic cross-sectional view of an organic light-emitting device according to a first embodiment;

FIG. 2 illustrates a graph of a relation between taper angle of a low refractive layer and out-coupling efficiency;

FIG. 3 illustrates a schematic cross-sectional view for showing a trace of a light path;

FIG. 4 illustrates a cross-sectional view of an organic light-emitting device including a low refractive layer formed in a regular pattern at a taper angle of 45° according to a second embodiment;

FIG. 5 illustrates a cross-sectional view of a comparative organic light-emitting device including a low refractive layer formed at a taper angle of 90°;

FIG. 6 illustrates a graph of a relation between normalized power values (for the OLED of FIG. 4 and the OLED of FIG. 5) and a size of a photoreceiver;

FIG. 7 illustrates a graph of first-order derivatives of the normalized power values of FIG. 6;

FIGS. 8A and 8B illustrate schematic cross-sectional views of organic light-emitting devices according to third and fourth embodiments;

FIG. 9 illustrates a graph of a relation between a refractive index of a micro-lens array (MLA) and out-coupling efficiency;

FIG. 10 illustrates a cross-sectional view of an MLA showing traces of paths of light rays according to a refractive index of the MLA;

FIG. 11 illustrates a graph of a relation between a taper angle of a low refractive layer and out-coupling efficiency according to the refractive index of an MLA;

FIG. 12 illustrates a schematic cross-sectional view of an organic light-emitting device according to a fifth embodiment;

FIG. 13 illustrates a graph of a relation between taper angle of a high refractive layer and out-coupling efficiency; and

FIG. 14 illustrates a schematic cross-sectional view showing traces of a light path for an organic light-emitting device according to an embodiment.

### DETAILED DESCRIPTION

Korean Patent Application No. 10-2009-0123991, filed on Dec. 14, 2010, in the Korean Intellectual Property Office, and entitled: “Organic-Light Emitting Device, Light Equipment Including the Same, and Organic Light-Emitting Display Apparatus Including the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

FIG. 1 illustrates a schematic cross-sectional view of an organic light-emitting device 100 according to a first embodiment.

In the example embodiment illustrated in FIG. 1, the organic light-emitting device 100 includes a substrate 110, a first electrode layer 120, a low refractive layer 130, an organic light-emitting layer 140, and a second electrode layer 150.

The substrate 110 may be, e.g., a glass substrate using SiO₂ as a main component, a plastic substrate, or a substrate formed of various types of materials. The organic light-emitting device 100 of the present embodiment may be applied to a top-emission organic light-emitting device (for emitting light toward the second electrode layer 150), may be applied to a bottom-emission organic light-emitting device (for emitting light toward the substrate 110), or may be applied to a two-sided emission organic light-emitting device. In the following description, the organic-light emitting device 100 of the present embodiment is a bottom-emission organic light-emitting device which emits the light toward the substrate 110. In this case, the substrate 110 is a transparent substrate.

In the example embodiment shown in FIG. 1, the first electrode layer 120 is disposed on the substrate 110. The first electrode layer 120 may be a transparent electrode and may be formed of, e.g., indium tin oxide (ITO) having a refractive index (n) of about 1.8. In another implementation, the first electrode layer 120 may be a transparent electrode including, e.g., indium zinc oxide (IZO), ZnO, or In₂O₃.

The low refractive layer 130 may have a lower refractive index than the first electrode 120 and/or the organic light-emitting layer 140. The low refractive layer 130 may be regularly patterned on the first electrode layer 120, and may have a pattern such as a grid pattern, a check pattern, a randomly distributed pattern, or other various types of patterns.

The refractive index of the low refractive layer 130 may be lower than a refractive index of ITO (n=1.8). The refractive index of the low refractive layer 130 may be lower than a refractive index of the organic light-emitting layer 140 (n=1.7-1.8). The refractive index of the low refractive layer 130 may be about 1 to about 1.55 in the present embodiment. In an implementation, the refractive index of the low refractive layer 130 may be at least 1 and up to 1.55. The low refractive layer 130 may include a material that is transparent to visible light, e.g., one or more of a porous material, a fluorinated compound, an oxide, a nitride, a silicon compound, or a polymer organic material. In an implementation, the low refractive layer 130 may include SiO₂ as the material that is transparent to visible light.

The low refractive layer 130 may have a patterned end, which may form a taper with an angle “θ” that is about 20° to about 60° with a surface of the first electrode layer 120. In an implementation, the taper angle “θ” may be about 30° to about 60°.

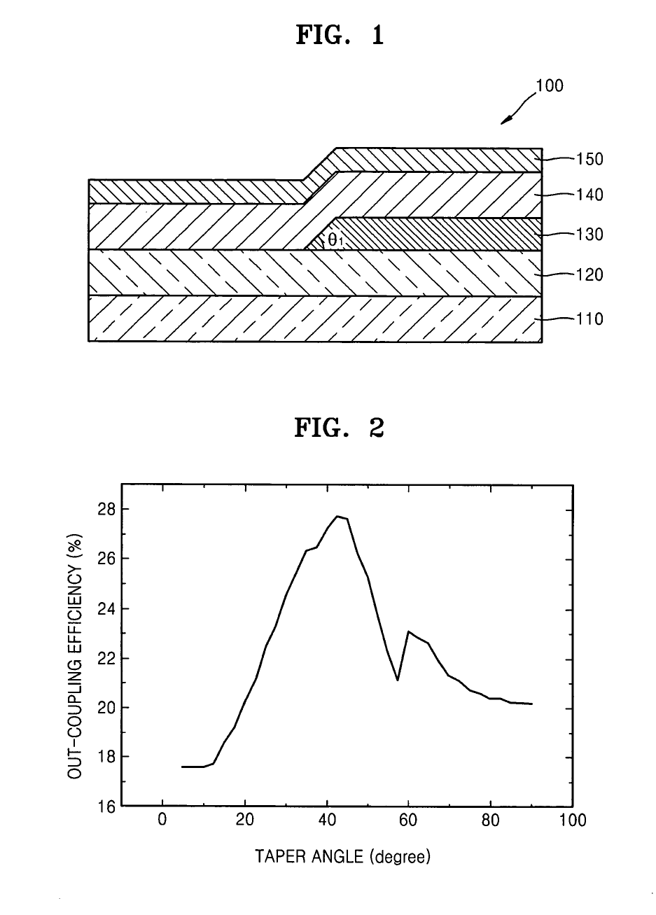

FIG. 2 illustrates a graph of a relation between taper angle of a low refractive layer and out-coupling efficiency.

As shown in FIG. 2, when the taper angle is between about 20° and about 60°, the out-coupling efficiency is more than 20%. When the taper angle is between about 30° and about 60°, the out-coupling efficiency is more than or equal to 23%. Thus, the out-coupling efficiency of an organic light-emitting device according to an embodiment may be higher than out-coupling efficiency of a general organic light-emitting device, which is within a range between 16% and 18%.

In the example embodiment shown in FIG. 1, the organic light-emitting layer 140 is formed on the low refractive layer 130 so as to contact the patterned end of the low refractive layer 130. The organic light-emitting layer 140 may be formed as a multi-layered structure formed of several types of materials and may further include an inorganic material layer. The organic light-emitting layer 140 may be formed of, e.g., a small molecular weight organic material or polymer organic material.

If the organic light-emitting layer 140 is formed of the small molecular weight organic material organic material, a hole injection layer (HIL) (not shown), a hole transport layer (HTL) (not shown), an electron transport layer (ETL) (not shown), an electron injection layer (EIL) (not shown), and the like may be stacked in a single or complex structure with the organic light-emitting layer 140, with the organic light-emitting layer 140 disposed among the HIL, the HTL, the ETL, the EIL, and the like. Copper phthalocyanine (CuPc), N,N′-di(naphthalene-1-yl)-N,N′-diphenyl-benzidine (NPB), tris-8-hydroxyquinoline aluminum (Alq3), or the like may be used as an organic material of the organic light-emitting layer 140. If the organic light-emitting layer 140 is formed of the polymer organic material, a HIL (not shown) may be further formed from the organic light-emitting layer 140 toward an anode electrode. In this case, the HIL may be formed of poly(3,4-ethylenedioxythiophene) (PEDOT), and the organic light-emitting layer 140 may be formed of a polymer organic material such as poly-phenylenevinylene (PPV), polyfluorene, and the like.

In the example embodiment shown in FIG. 1, the second electrode layer 150 is formed on the organic light-emitting layer 140. The second electrode layer 150 may be a transparent electrode in the top-emission organic light-emitting device, or may be a reflective electrode in the bottom-emission organic light emitting device. If the second electrode 150 is a reflective electrode in the bottom-emission organic light-emitting device, as in the present embodiment, the second electrode 150 may be formed of, e.g., Li, Ca, LiF/Ca, LiF/Al, Al, or Mg, or may be formed of a compound of Li, Ca, LiF/Ca, LiF/Al, Al, or Mg, etc.

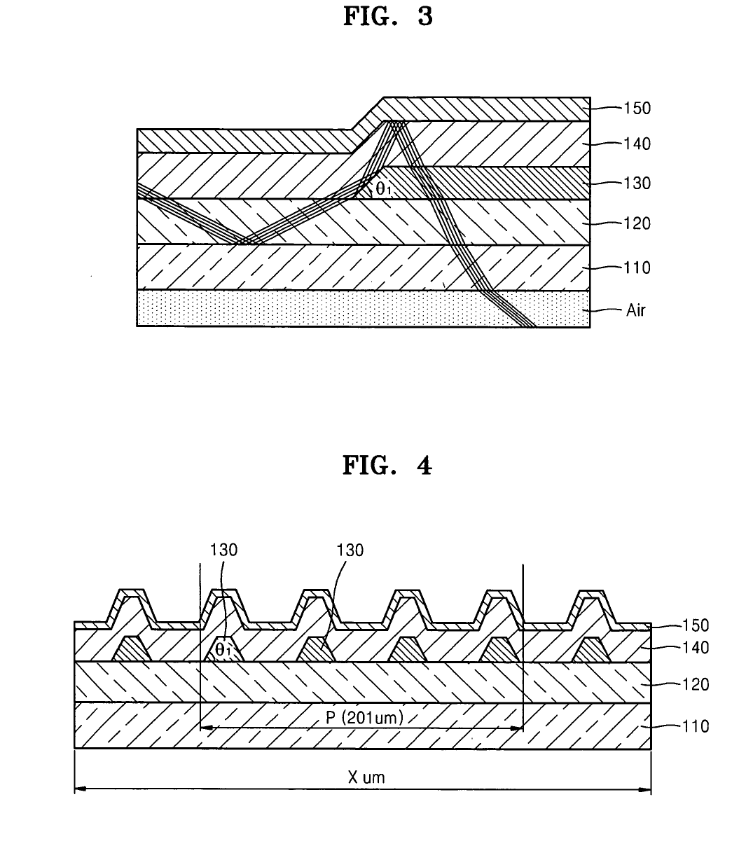

FIG. 3 illustrates a schematic cross-sectional view for showing a trace of a light path.

Referring to FIG. 3, light emitted from the organic light-emitting layer 140 is reflected from a surface of the low refractive layer 130, which may have a taper angle between about 30° and about 60°. The light is reflected from an upper metal electrode, i.e., the second electrode layer 150, to be emitted outside the substrate 110, i.e., to the air. Thus, the low refractive layer 130 may operate as a kind of total reflection mirror. Accordingly, a ratio of emitting light that has been reflected from the low refractive layer 130 one time to the air is relatively high. In this case, a probability of emitting light generated from one pixel from the corresponding pixel to the outside becomes high. Thus, FIG. 3 illustrates that out-coupling efficiency may be improved, and an increase in pixel blurring may be inhibited, in an organic light-emitting device according to an embodiment.

If an end of the low refractive layer 130 does not have a predetermined taper angle, i.e., if the end of the low refractive layer has a taper angle of 90°, a refractive index of the low refractive layer 130 is approximately 1 to refract light through the low refractive layer 130 one time and then emit the reflected light to the outside. If the low refractive layer 130 is formed of a low refractive material such as SiO₂ using a well-known process, light is refracted from the low refractive layer 130 several times, and refraction angles of the light are summed to be emitted to the outside. This case indicates that a probability of emitting light generated from and trapped in one pixel through a next pixel to the outside becomes high. Thus, if the end of the low refractive layer has a taper angle of 90°, pixel blurring or cross-talking between pixels are not inhibited, and a path of the light guided through an ITO layer or the like becomes longer. As a result, a probability of absorbing the light is high, which does not increase out-coupling efficiency.

This will now be described in more detail with reference to FIGS. 4 through 7.

FIG. 4 illustrates a cross-sectional view of an organic light-emitting device 130 including a low refractive layer formed in a regular pattern at a taper angle of 45° according to a second embodiment. FIG. 5 illustrates a cross-sectional view of a comparative organic light-emitting device including a low refractive layer 30 having a taper angle of 90°.

Each light emitting part “P” is distributed within a range of 201 μm×201 μm so as to correspond to the size of one pixel. Each of the low refractive layers 130 and 30 is widely distributed in a regular pattern having a size of 3 μm×3 μm within a range between 10,000 μm×1,000 μm in order to check effects on adjacent pixels. Each substrate 110 and 10 is formed to a thickness of 700 μm.

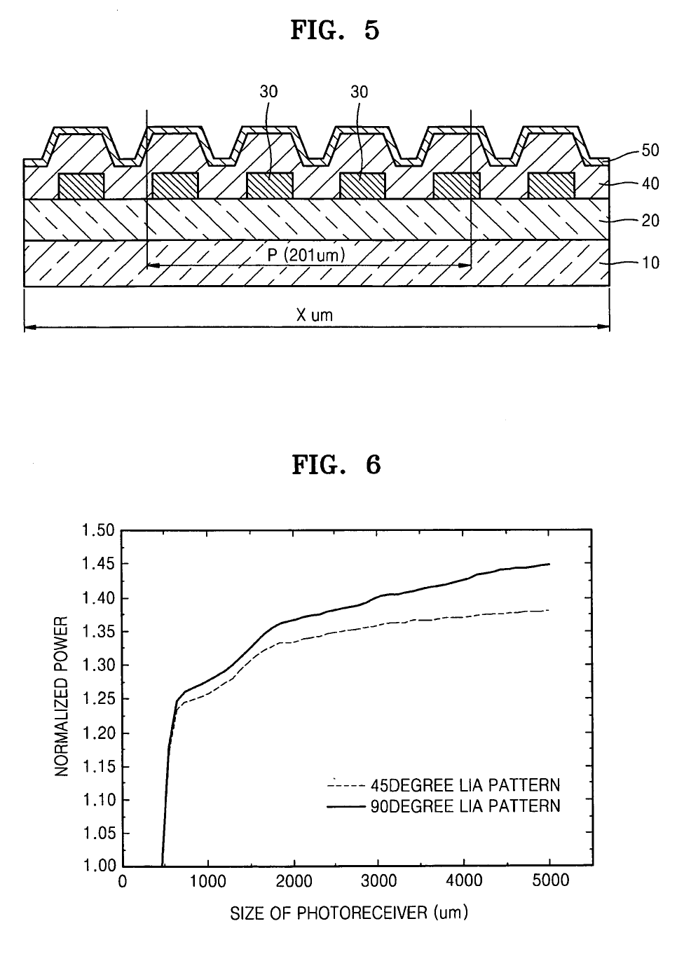

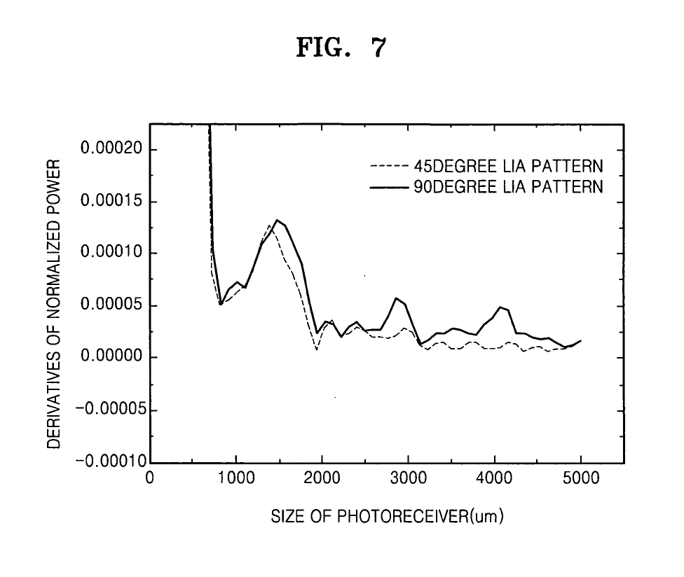

FIG. 6 illustrates a graph of normalized power values of the OLED of FIG. 4 and the OLED of FIG. 5 according to a size of a photoreceiver. FIG. 7 illustrates a graph of first-order derivatives of the normalized power values of FIG. 6;

Referring to FIG. 6, power values for a low refractive layer with a taper angle of 45° in accordance with an embodiment are collected by the photoreceiver over a size ranging from 461 μm×461 μm to 5000 μm×5000 μm. Similarly, power values for a general refractive layer with a taper angle of 90° are collected by the photoreceiver over a size ranging from 461 μm×461 μm to 5000 μm×5000 μm. As evident from FIG. 6, the power values of the present invention are comparable with the general power values.

If the low refractive layer 130 has the taper angle of 45°, a photoreceiver having a size of 1400 μm×1400 μm receives most of the power of light emitted from a pixel having a size of 201 μm×201 μm. Thus, although the size of the photoreceiver is increased, the power hardly changes. If the low refractive layer 30 has the taper angle of 90°, power of light emitting from a pixel having a size of 201 μm×201 μm is continuously increased after the size of the pixel is increased to 1400 μm×1400 μm. In other words, photons having a low probability of meeting the low refractive layer 30 having the taper angle of 90° one time and being emitted outside the substrate 10 are reflected from the substrate 10, meet the low refractive layer 30 two times, and emitted. Sometimes, a few of the photons meet the low refractive layer 30 three times and are emitted. However, photons which have met the low refractive layer 130 having the taper angle of 45° are mostly emitted when meeting the low refractive layer 130 two times.

Referring to FIG. 7, if the low refractive layer 30 has the taper angle of 90°, a large amount of light is emitted outside a pixel. In particular, when the size of the photoreceiver is changed to about 1,400 μm, 2,800 μm, and 4,200 μm, an increase of a power value transmitted to the photoreceiver becomes a local maximum. A total reflection threshold angle on an interface between air and a substrate is set to about 45°, photons, which pass the low refractive layer 30 one time and are converted into a glass guided mode, re-meet the low refractive layer 30 at a distance of a substrate thickness*(700 μm*2) in a horizontal direction.

As described above, an organic light-emitting device including a low refractive layer having a predetermined taper angle “θ” may improve out-coupling efficiency and inhibits an increase in pixel blurring in comparison with an organic light-emitting device including a low refractive layer having a taper angle of 90°. Light equipment including the organic light-emitting device and an organic light-emitting display (OLED) apparatus including the organic-light emitting device may also improve out-coupling efficiency and inhibit an increase in pixel blurring.

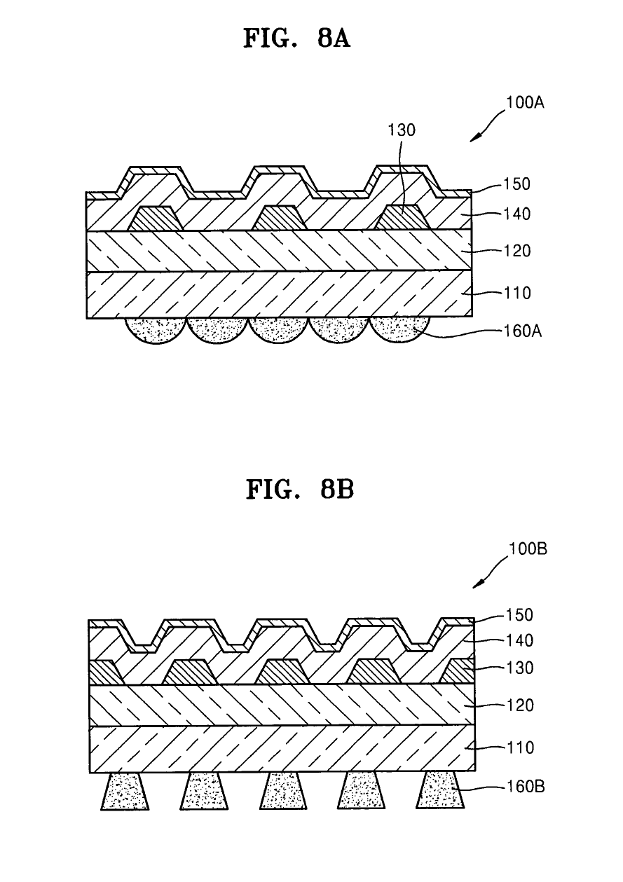

FIGS. 8A and 8B illustrate schematic cross-sectional views of organic light-emitting devices 100A and 100B according to third and fourth embodiments.

In the third and fourth embodiments, respective microlens arrays 160A and 160B are shown. Referring to FIGS. 8A and 8B, the organic light-emitting devices 100A and 100B include a substrate 110, a first electrode layer 120, a low refractive layer 130 patterned to have a predetermined taper angle, an organic light-emitting layer 140, a second electrode layer 150, and the respective microlens array (MLA) 160A or 160B.

The organic light-emitting device 100A, 100B may otherwise be the same as the organic light-emitting device 100, i.e., apart from further including the MLA 160A or 160B. Thus, the following description will focus on the microlens arrays of the organic light-emitting devices 100A, 100B.

The MLA 160A or 160B may be formed on an outer surface of the substrate 110. In the example embodiment shown in FIG. 8A, the organic light-emitting device 100A includes the MLA 160A having a dense hexagonal hemispheric shape. In the example embodiment shown in FIG. 8B, the organic light-emitting device 100B includes the MLA 160B having a reversed trapezoidal shape. The MLAs 160A and 160B are merely examples, and may have various other shapes. The MLAs 160A and 160B may include one or more materials transparent to visible light, e.g., an oxide, a nitride, a silicon compound, a polymer organic material, etc. The MLAs 160A and 160B may have a uniform interval, and a size or an interval of the MLA 160A or 160B may be larger than a wavelength of emitted light. Thus, the dependence of the MLA 160A or 160B on a wavelength of light in a visible light range may be reduced.

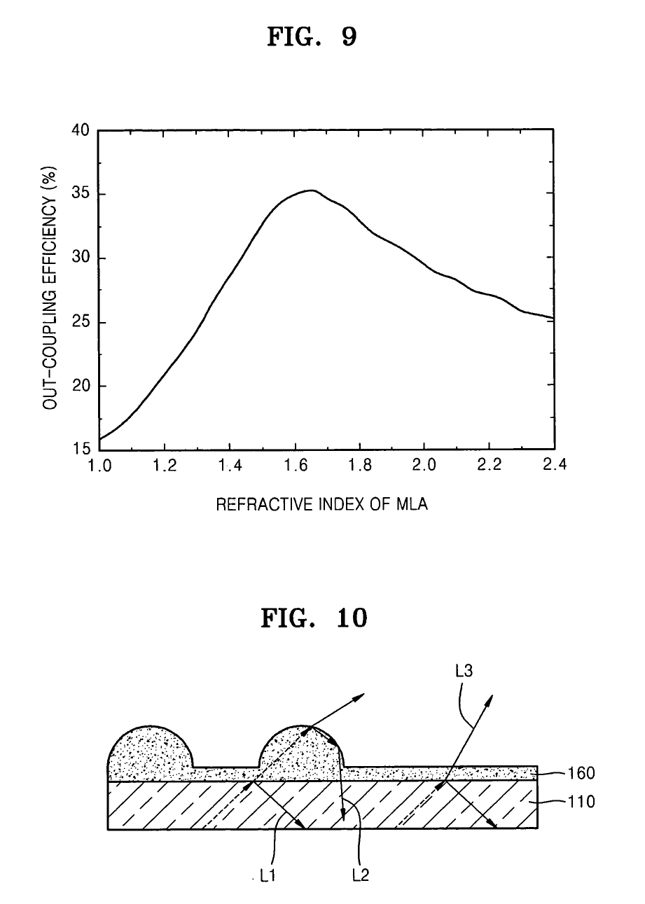

FIG. 9 illustrates a graph of a relation between a refractive index of a micro-lens array (MLA) and out-coupling efficiency. FIG. 10 illustrates a cross-sectional view of an MLA showing traces of paths of light rays according to a refractive index of the MLA.

Referring to FIG. 9, an improvement in the degree of out-coupling efficiency varies with the refractive index of the MLA. In particular, when the refractive index of the MLA is about 1.65, the out-coupling efficiency is maximized in FIG. 9.

In the representations shown in FIG. 10, if a refractive index of the MLA 160 is lower than that of the substrate 110 (refer to ray “L1” in FIG. 10), a total reflection of light occurs on an interface between the substrate 110 and the MLA 160. Thus, an amount of light trapped in the substrate 110 is increased. If the refractive index of the MLA 160 is higher than that of the substrate 110 (refer to ray “L2” in FIG. 10), a total reflection of light occurs on an interface between the MLA 160 and air. Thus, the refractive index of the MLA 160 may be set to be equal to, or slightly higher than, that of the substrate 110 (e.g., the MLA 160 may have a refractive index of about 1.45 to about 1.8) in order to optimize the out-coupling efficiency (refer to ray “L3” in FIG. 10).

As described above, the out-coupling efficiency may be improved by using the MLA 160 alone. However, the out-coupling efficiency may be maximized when both the MLA 160 and the low refractive layer 130 patterned to have a predetermined angle are used together. The MLA 160 may emit only a portion of light trapped in the substrate 110 to the outside. Thus, if the MLA 160 and the low refractive layer 130 are used together, light trapped in the organic light-emitting layer 140 and the first electrode layer 120 may be converted into the light refracted from the low refractive layer 130 and trapped in the substrate 100. The light is finally emitted through the MLA 160 to the outside. Thus, out-coupling efficiency may be significantly improved.

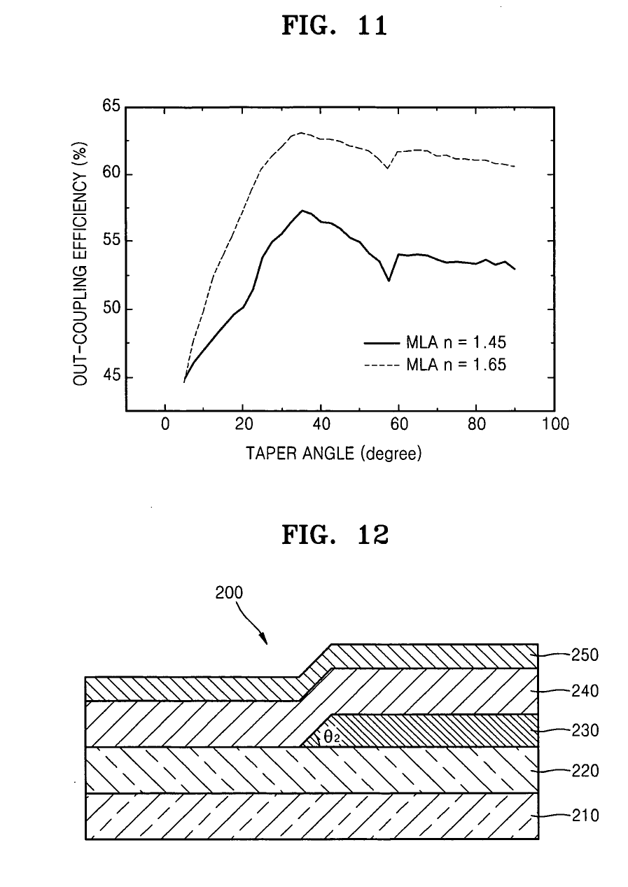

FIG. 11 illustrates a graph of a relation between a taper angle of a low refractive layer and out-coupling efficiency according to the refractive index of an MLA.

The out-coupling efficiency of an organic light-emitting device including the MLA and the low refractive layer is illustrated in FIG. 11. Referring to FIG. 11, out-coupling efficiency of the organic light-emitting device including the MLA having a refractive index of 1.65 is higher than out-coupling efficiency of the organic light-emitting device including the MLA having a refractive index of 1.45. If the low refractive layer has an appropriate taper angle, out-coupling efficiency may be optimized. For example, when the refractive index of the MLA is between about 1.45 and about 1.8, and the taper angle of the low refractive layer is between about 30° and about 60°, the out-coupling efficiency may be optimized.

Organic light-emitting devices according to embodiments of the present invention will now be described with reference to FIGS. 12 through 14.

FIG. 12 illustrates a schematic cross-sectional view of an organic light-emitting device 200 according to a fifth embodiment.

In the example embodiment shown in FIG. 12, the organic light-emitting device 200 includes a substrate 210, a first electrode layer 220, a high refractive layer 230, an organic light-emitting layer 240, and a second electrode layer 250.

The organic light-emitting device 200 includes the high refractive layer 230 instead of the low refractive layer 130 of the organic light-emitting device 100 of the first embodiment, and characteristics relating to this difference will be described in detail below.

The organic light-emitting device 200 may be applied to a top-emission organic light emitting device (which emits light toward the second electrode layer 250), may be applied to a bottom-emission organic light emitting device (which emits light toward the substrate 210), or may be applied to a two-sided light emitting device. The organic light-emitting device 200 that will be described below is a bottom-emission organic light emitting device. In this case, the substrate 210 may be formed of, e.g., transparent glass, and the first electrode layer 220 may be a transparent electrode formed of, e.g., ITO.

The high refractive layer 230 may have a higher refractive index than the first electrode layer 220. The high refractive layer 230 may have a higher refractive index than the organic light-emitting layer 240. The high refractive layer 230 may have a higher refractive index may be regularly patterned on the first electrode 220. The high refractive layer 230 may have a grid pattern, a check pattern, a random pattern, or the like.

The refractive index of the high refractive layer 230 may be higher than a refractive index of the ITO (n=1.8) of the first electrode layer 220. The refractive index of the high refractive layer 230 may be higher than a refractive index of the organic light-emitting layer 240 (n=1.7˜1.8). The refractive index of the high refractive layer 230 may be about 1.9 to about 2.8. The high refractive layer 230 may include a material transparent to visible light, e.g., a carbide, an oxide, a nitride, a sulfide, and/or a selenium (Se) compound.

A patterned end of the high refractive layer 230 may form a taper angle “θ” of about 20° to about 60° with a surface of the first electrode layer 220.

In the example embodiment shown in FIG. 12, the organic light-emitting layer 240 is formed on a high refractive layer 230 to contact a patterned end of the high refractive layer 230. The organic light-emitting device 240 may be formed as a multi-layered structure including several types of materials and may further include an inorganic material layer. The organic light-emitting layer 240 may be formed of, e.g., a small molecular weight organic material or polymer organic material. This is the same as that of the first embodiment, and thus its description will be not be repeated here.

In the example embodiment shown in FIG. 12, the second electrode layer 250 is formed on the organic light-emitting layer 240. When the second electrode layer 250 is a reflective electrode in a bottom-emission organic light emitting device, the second electrode layer 250 may be formed of Li, Ca, LiF/Ca, LiF/Al, Al, or Mg, or may be formed a compound of Li, Ca, LiF/Ca, LiF/Al, Al, or Mg, etc.

The high refractive layer 230 of the organic light-emitting device 200 may be regularly patterned to have a predetermined taper angle, as in the first embodiment. Thus, out-coupling efficiency may be improved, and an increase in pixel blurring may be inhibited. An MLA (not shown in FIG. 12; see FIGS. 4 and 5) may be formed on an outer surface of the substrate 210 in order to maximize out-coupling efficiency.

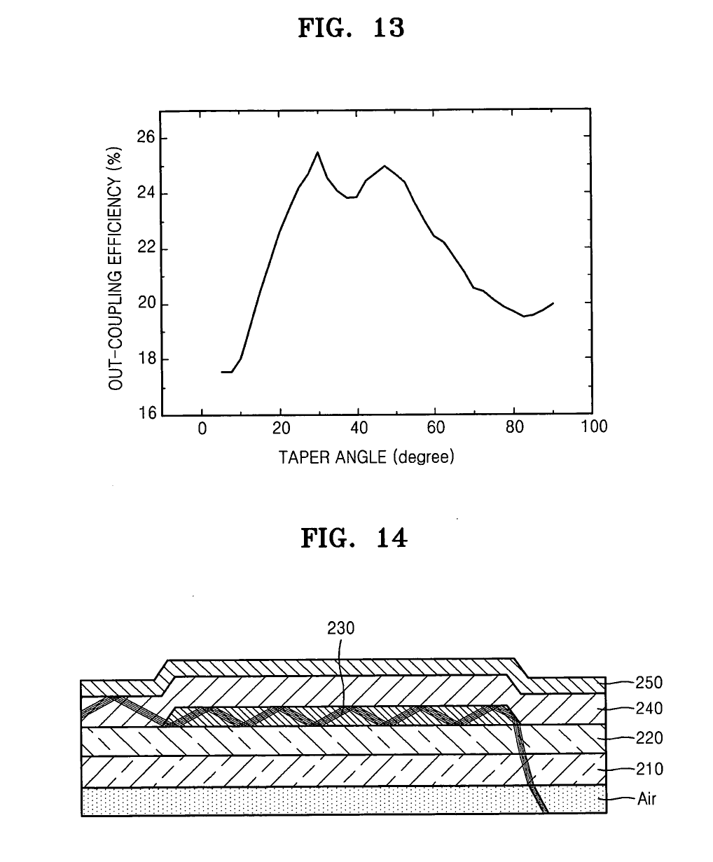

FIG. 13 illustrates a graph of a relation between taper angle of a high refractive layer (n=2.4) and out-coupling efficiency. FIG. 14 illustrates a schematic cross-sectional view showing traces of a light path for an organic light-emitting device according to an embodiment.

Referring to FIGS. 13 and 14, when the taper angle is between about 20° and about 60°, the out-coupling efficiency is more than 21%, which is higher than out-coupling efficiency of a general light emitting device that is between 16% and 18%.

Therefore, an organic light-emitting device including a high refractive layer having a predetermined taper angle “θ” may improve out-coupling efficiency and inhibit an increase in pixel blurring in comparison with an organic light-emitting device including a high refractive layer having a taper angle of 90°. Also, light equipment including the organic light-emitting device and an OLED apparatus including the organic light-emitting device may also improve the out-coupling efficiency and inhibit the increase in pixel blurring.

As described above, an organic light-emitting device including a refractive layer having a predetermined taper angle “θ” according to embodiments may improve out-coupling efficiency. Light equipment including the organic light-emitting device and an OLED apparatus including the organic light-emitting device may also exhibit improved out-coupling efficiency. Further, where the organic light-emitting device and the OLED apparatus are used without an MLA, the organic light-emitting device and the OLED apparatus may improve out-coupling efficiency with an inhibition of pixel blurring.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. An organic light-emitting device, comprising:
a substrate;
a first electrode layer on the substrate;
a patterned refractive layer on the first electrode layer, a taper angle between a patterned end of the refractive layer and a surface of the first electrode being about 20 to about 60 degrees, the refractive layer including a material having a different refractive index from that of one of the first electrode layer and an organic light-emitting layer;
the organic light-emitting layer that covers the refractive layer and is on the first electrode, the organic light-emitting layer contacting the patterned end of the refractive layer; and
a second electrode layer on the organic light-emitting layer.

2. The organic light-emitting device as claimed in claim 1, wherein at least one of the first and second electrode layers is a transparent electrode.

3. The organic light-emitting device as claimed in claim 1, wherein the refractive layer has a lower refractive index than that of one of the organic light-emitting layer and the first electrode layer

4. The organic light-emitting device as claimed in claim 3, wherein the refractive index of the refractive layer is about 1 to about 1.55.

5. The organic light-emitting device as claimed in claim 3, wherein the refractive layer is transparent to visible light, and includes at least one of a porous material, a fluorinated compound, an oxide, a nitride, a silicon compound, and a polymer organic material.

6. The organic light-emitting device as claimed in claim 3, wherein the taper angle is about 30 to about 60 degrees.

7. The organic light-emitting device as claimed in claim 3, wherein the refractive layer is regularly patterned, and is parallel with the first and second electrode layers.

8. The organic light-emitting device as claimed in claim 7, wherein a periodic interval of the pattern of the refractive layer is larger than a wavelength of light emitted from the organic light-emitting device.

9. The organic light-emitting device as claimed in claim 7, wherein the taper angle is about 30 to about 60 degrees.

10. The organic light-emitting device as claimed in claim 1, wherein the refractive layer has a higher refractive index than that of one of the organic light-emitting layer and the first electrode layer.

11. The organic light-emitting device as claimed in claim 10, wherein the refractive index of the refractive layer is about 1.9 to about 2.8.

12. The organic light-emitting device as claimed in claim 10, wherein the refractive layer is transparent to visible light, and includes at least one of a carbide, an oxide, a nitride, a sulfide, and a selenium compound.

13. The organic light-emitting device as claimed in claim 10, wherein the refractive layer is regularly patterned, and is parallel with the first and second electrode layers.

14. The organic light-emitting device as claimed in claim 10, wherein a periodic interval of the regularly patterned refractive layer is larger than a wavelength of light emitted from the organic light-emitting device.

15. The organic light-emitting device as claimed in claim 10, wherein the taper angle is about 30 to about 60 degrees.

16. The organic light-emitting device as claimed in claim 1, further comprising a microlens array (MLA) on an outer surface of the substrate, the MLA having a refractive index of about 1.45 to about 1.8.

17. The organic light-emitting device as claimed in claim 16, wherein the MLA has a periodic interval.

18. The organic light-emitting device as claimed in claim 16, wherein a size and a periodic interval of the MLA are larger than a wavelength of light emitted from the organic light-emitting device.

19. The organic light-emitting device as claimed in claim 16, wherein the MLA is transparent to visible light, and includes at least one of an oxide, a nitride, a silicon compound, and a polymer organic material.

20. A light equipment, comprising:
the organic light-emitting device as claimed in claim 1.

21. An organic light emitting display apparatus, comprising:
the organic light-emitting device as claimed in claim 1.
